(19) United States
(12) Patent Application Publication
(10) Pub. No.: US 2025/0199126 A1
(43) Pub. Date: Jun. 19, 2025

(54) LIGHT EMITTING DEVICE AND DISTANCE MEASUREMENT APPARATUS

(71) Applicant: FUJIFILM Business Innovation Corp., Tokyo (JP)

(72) Inventors: Kei TAKEYAMA, Kanagawa (JP); Daisuke IGUCHI, Kanagawa (JP); Tomoaki SAKITA, Kanagawa (JP); Yoshihiro YAMAMOTO, Kanagawa (JP); Junichiro HAYAKAWA, Kanagawa (JP)

(73) Assignee: FUJIFILM Business Innovation Corp., Tokyo (JP)

(21) Appl. No.: 18/673,353

(22) Filed: May 24, 2024

(30) Foreign Application Priority Data
Dec. 13, 2023 (JP) 2023-210102

(51) Int. Cl. G01S 7/481; G01S 17/08

(52) U.S. Cl. CPC G01S 7/4814; G01S 17/08

(57) ABSTRACT

A light emitting device includes a light emitting unit that irradiates different irradiation regions with light beams from plural light sources in parallel, and a control unit that turns off a part of the plural light sources that irradiate, with light beams, an overlapping region where the irradiation regions by the respective light sources overlap each other in a case where an entry of a target object into the overlapping region is detected.

### CROSS-REFERENCE TO RELATED APPLICATIONS

This application is based on and claims priority under 35 USC 119 from Japanese Patent Application No. 2023-210102 filed Dec. 13, 2023.

### BACKGROUND

### (i) Technical Field

The present invention relates to a light emitting device and a distance measurement apparatus.

### (ii) Related Art

JP2020-160044A discloses a distance measurement apparatus that causes a light source to preliminarily emit light, controls an intensity of light emitted by regular light emission based on an intensity of light received in each light reception region, and measures a distance to a distance measurement target.

JP2018-120989 discloses a three-dimensional measurement apparatus that includes a human sensor detecting a person and controls output of laser light depending on whether or not information indicating that there is no person in a detection region is received.

### SUMMARY

There is a distance measurement apparatus that measures a distance to a target object by a so-called time of flight (ToF) method in which a time from emission of light to reception of the light reflected by the target object is measured. In such a distance measurement apparatus, a plurality of light sources irradiate different regions with light beams, whereby distance measurement of a wider region can be performed as compared with a case of a single light source.

However, in a case where light beams from the plurality of light sources are emitted to different irradiation regions in parallel, an overlap between the irradiation regions may occur depending on a distance from the light sources. In an overlapping region where the irradiation regions overlap each other, the intensity of light increases, so that the intensity of light emitted to the target object is excessive in a case where the target object enters the overlapping region.

Aspects of non-limiting embodiments of the present disclosure relate to a light emitting device and a distance measurement apparatus that prevent an intensity of light emitted to a target object that enters an overlapping region from being excessive as compared with a case where a part of a plurality of light sources that emit light beams causing an overlap between irradiation regions is not turned off.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting device including a light emitting unit that irradiates different irradiation regions with light beams from a plurality of light sources in parallel, and a control unit that turns off a part of the plurality of light sources that irradiate, with light beams, an overlapping region where the irradiation regions by the respective light sources overlap each other in a case where an entry of a target object into the overlapping region is detected.

### BRIEF DESCRIPTION OF THE DRAWINGS

Exemplary embodiment(s) of the present invention will be described in detail based on the following figures, wherein:

FIG. 1 is a block diagram showing an example of a schematic configuration of a distance measurement apparatus to which a first exemplary embodiment is applied;

FIG. 2 is a diagram describing a relationship between a light emitting unit according to the first exemplary embodiment and an irradiation region that is irradiated with light from the light emitting unit;

FIG. 3 is a diagram describing a relationship between the light emitting unit according to the first exemplary embodiment and irradiation surfaces that are irradiated with light beams emitted from the light emitting unit;

FIG. 4 is a diagram describing a relationship between the light emitting unit in a case where a plurality of light sources are disposed such that an overlapping region extends in a direction intersecting an entry direction of a target object, and irradiation surfaces that are irradiated with light beams emitted from the light emitting unit;

FIG. 5 is a diagram describing a relationship between the light emitting unit in a case where three or more light sources are disposed such that an overlapping region extends in the direction intersecting the entry direction of the target object, and irradiation surfaces that are irradiated with light beams emitted from the light emitting unit;

FIG. 6 is a diagram showing a configuration example of a light emitting unit provided in a distance measurement apparatus to which a second exemplary embodiment is applied;

FIG. 7 is a diagram describing a relationship between the light emitting unit according to the second exemplary embodiment and an irradiation region that is irradiated with light from the light emitting unit;

FIG. 8 is a diagram describing a relationship between the light emitting unit according to the second exemplary embodiment and irradiation surfaces that are irradiated with light beams emitted from the light emitting unit;

FIG. 9 is a diagram describing a relationship between a light receiving surface of a light receiving unit according to the second exemplary embodiment and the irradiation surfaces described above;

FIG. 10 is a flowchart showing a procedure of processing by a control unit;

FIG. 11 is a diagram describing a relationship between the light emitting unit in a case where the light emitting unit according to the second exemplary embodiment has four light sources, and an irradiation region that is irradiated with light from the light emitting unit;

FIG. 12 is a diagram describing a relationship between the light emitting unit in a case where the light emitting unit according to the second exemplary embodiment has four light sources, and an irradiation surface that is irradiated with light from the light emitting unit;

FIG. 13 is a diagram describing a relationship between the light emitting unit in a case where the light emitting unit according to the second exemplary embodiment has four light sources, and an irradiation surface that is irradiated with light from each light source;

FIG. 14 is a diagram describing an overlapping region between irradiation regions in a case where the light emitting unit according to the second exemplary embodiment has four light sources; and

FIG. 15 is a diagram describing a relationship between the light emitting unit in a case where a plurality of light sources of the light emitting unit in which a light emitting surface is divided into a plurality of light emitting sections are disposed such that an overlapping region extends in the direction intersecting the entry direction of the target object, and an irradiation surface that is irradiated with light emitted from the light emitting unit.

### DETAILED DESCRIPTION

Hereinafter, exemplary embodiments of the present invention will be described in detail with reference to the accompanying drawings.

### First Exemplary Embodiment

### Distance Measurement Apparatus 1

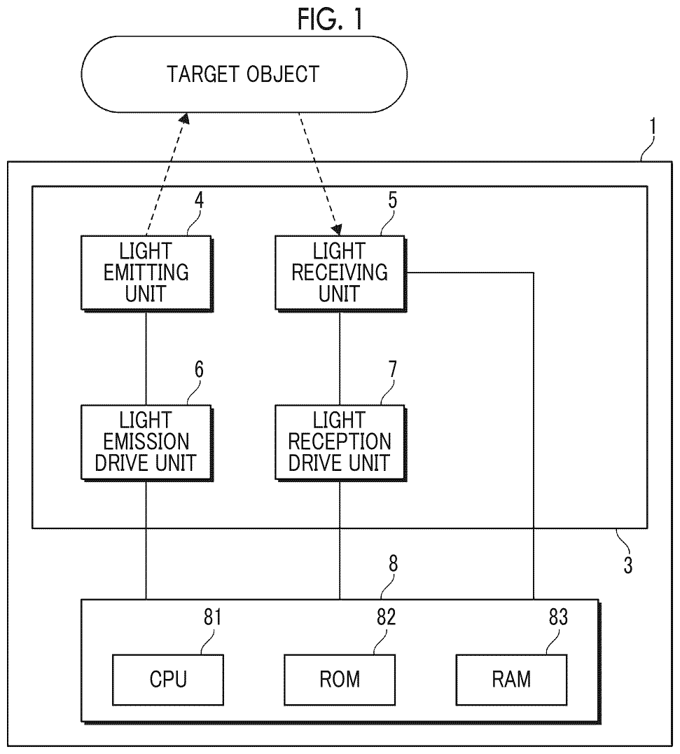

FIG. 1 is a block diagram showing an example of a schematic configuration of a distance measurement apparatus 1 to which a first exemplary embodiment is applied.

The distance measurement apparatus 1 measures a distance to a target object based on a result of receiving light emitted from a light emitting unit 4 to be described below and reflected by the target object with a light receiving unit 5 to be described below. The distance measurement apparatus 1 measures a distance from the distance measurement apparatus 1 to the target object based on a time of flight (ToF) method, for example. In addition, the distance measurement apparatus 1 measures the distance to the target object based on a time from a timing at which light is emitted from the light emitting unit 4 to a timing at which the emitted light is reflected by the target object and received by the light receiving unit 5. The ToF method includes an indirect ToF (iToF) method in which a time is measured from a difference between a phase of radiated light and a phase of received light, and a direct ToF (dToF) method in which a time from light radiation to light reception is directly measured. Here, the indirect ToF method and the direct ToF method are not distinguished and are described as the ToF method.

As shown in FIG. 1, the distance measurement apparatus 1 includes an optical device 3 and a control unit 8.

The optical device 3 includes the light emitting unit 4 that emits light toward a predetermined irradiation region, the light receiving unit 5 that receives light emitted from the light emitting unit 4 and reflected by the target object existing in the irradiation region, a light emission drive unit 6 that drives the light emitting unit 4, and a light reception drive unit 7 that drives the light receiving unit 5.

The control unit 8 controls the operations of the light emitting unit 4 and the light receiving unit 5 of the optical device 3.

In addition, the control unit 8 acquires a result of the light reception by the light receiving unit 5, and measures a distance from the distance measurement apparatus 1 to the target object by the ToF method based on a result of the light reception.

The control unit 8 is an example of a distance measurement unit.

### Light Emitting Unit 4

The light emitting unit 4 includes a plurality of light sources having a light emitting surface on which a plurality of vertical cavity surface emitting lasers (hereinafter, referred to as VCSELs) are arranged. The VCSEL is an example of a light emitting element.

The light emitting unit 4 irradiates different irradiation regions with light beams from the plurality of light sources in parallel. The light beams emitted from the respective light sources are spread and emitted onto a surface perpendicular to the emission direction by a diffusion unit (not shown). As the diffusion unit, an optical member such as a diffusion plate that is provided on an optical path of the light to diffuse the light with scattering or the like, and a diffractive optical element (DOE) or/and a lens that changes an angle of the incident light and emits the light can be used.

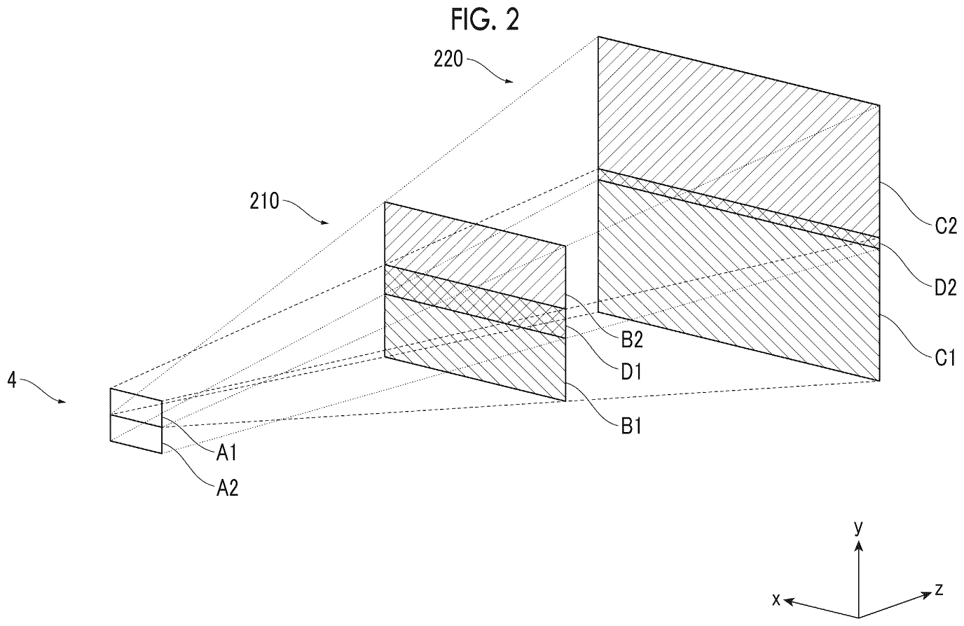

The light beams from the plurality of light sources of the light emitting unit 4 may be emitted in parallel or may be emitted to intersect each other. In a case of the light beams from the plurality of light sources, an overlap between the irradiation regions may occur depending on a distance from the light sources. The overlap between the irradiation regions will be described with reference to FIG. 2.

FIG. 2 is a diagram describing a relationship between the light emitting unit 4 according to the first exemplary embodiment and an irradiation region that is irradiated with light from the light emitting unit 4. FIG. 2 shows an example of a case where the light emitting unit 4 includes two light sources A1 and A2, and light beams from the light sources A1 and A2 are emitted to intersect each other. In FIG. 2, a left direction with respect to a direction in which the light emitting unit 4 emits the light beams is defined as an x direction, an upper direction of a paper plane is defined as a y direction, and the direction in which the light emitting unit 4 emits the light beams is defined as a z direction. In FIG. 2, the light source A1 is disposed in the upper direction (+y direction) of the paper plane with respect to the light source A2.

Each of the light sources A1 and A2 is independently driven by the light emission drive unit 6 (see FIG. 1) to emit light. The drive of the light sources A1 and A2 indicates that power is supplied to the VCSEL included in the light sources A1 and A2 and the VCSEL emits light. The term “independently driven” indicates that each of light sources A1 and A2 is driven to emit light. The light emission drive unit 6 drives each of the light sources A1 and A2 in response to a control signal from the control unit 8 (see FIG. 1).

Therefore, the light sources A1 and A2 in the example of FIG. 2 do not necessarily emit light simultaneously. For example, the light source A1 can emit light while the light source A2 does not emit light.

Irradiation regions that are irradiated with the light beams from the light sources A1 and A2 may have an overlapping region where the irradiation regions overlap each other depending on the distance from the light sources.

Irradiation surfaces 210 and 220 are surfaces that are irradiated with light beams from the light emitting unit 4, the surfaces being orthogonal to a direction in which light is emitted at a certain distance in a direction in which the light emitting unit 4 emits light, in the irradiation regions. In FIG. 2, the irradiation surface 220 is located in a direction (+z direction) away from the light emitting unit 4 with respect to the irradiation surface 210.

The irradiation surface 210 is formed of an irradiation surface B1 that is irradiated with light beams from the light source A1 and an irradiation surface B2 that is irradiated with light beams from the light source A2. In a case where the light beams from the light sources A1 and A2 are emitted to intersect each other, the light sources A1 and A2 are located in the −y direction in this order, whereas the irradiation surfaces B1 and B2 are located in the ty direction in this order. Partial regions of the irradiation surface B1 and the irradiation surface B2 in the y direction overlap each other, and an overlapping region D1 is formed.

The irradiation surface 220 is formed of an irradiation surface C1 that is irradiated with light beams from the light source A1 and an irradiation surface C2 that is irradiated with light beams from the light source A2. In a case where the light beams from the light sources A1 and A2 are emitted to intersect each other, the light sources A1 and A2 are located in the −y direction in this order, whereas the irradiation surfaces C1 and C2 are located in the +y direction in this order. Partial regions of the irradiation surface C1 and the irradiation surface C2 in the y direction overlap each other, and an overlapping region D2 is formed.

In a case where the light beams from the light sources A1 and A2 are emitted to intersect each other, the width of the overlapping region where the irradiation regions overlap each other is narrower in the y direction as the distance from the light emitting unit 4 increases. At a position further away from the light emitting unit 4 than the irradiation surface 220, the width of the overlapping region is further narrower, and no overlapping region is formed at a certain distance.

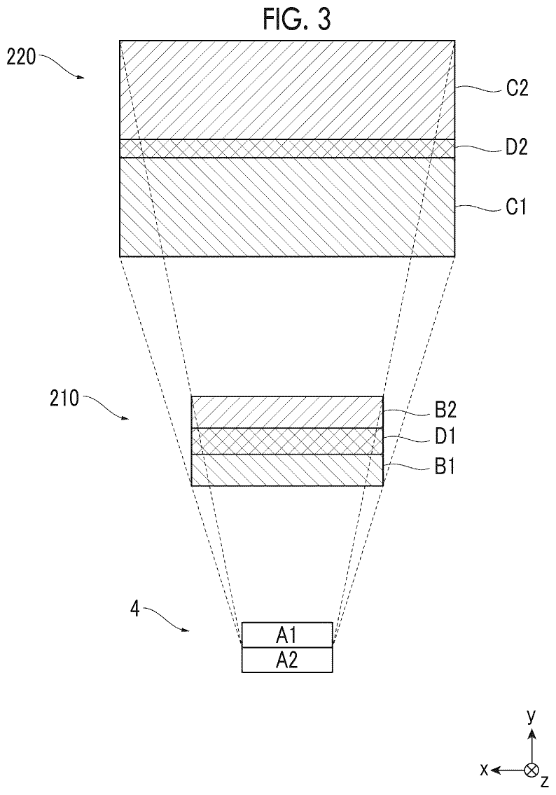

FIG. 3 is a diagram describing a relationship between the light emitting unit 4 according to the first exemplary embodiment and the irradiation surfaces 210 and 220 that are irradiated with light beams emitted from the light emitting unit 4. In FIG. 3, a left direction of the paper plane is defined as an x direction, an upper direction of the paper plane is defined as a y direction, and a back side direction of the paper plane is defined as a z direction. In FIG. 3, the light emitting unit 4 and the irradiation surfaces 210 and 220 are shown to be shifted in an up-down direction (+y direction) of the paper plane, but the light emitting unit 4 and the irradiation surfaces 210 and 220 are located to face each other. In FIG. 3, the light emitting unit 4 is located in the front side direction (−z direction) of the paper plane, the irradiation surface 210 is located in the back side direction (+z direction) of the paper plane, and the irradiation surface 220 is located in the back side direction (+z direction).

The irradiation surface 220 is located in the direction (+z direction) away from the light emitting unit 4 with respect to the irradiation surface 210, and the overlapping region D2 formed on the irradiation surface 220 has a narrower width in the y direction than the width of the overlapping region D1 formed on the irradiation surface 210.

### Light Receiving Unit 5

The light receiving unit 5 includes a light receiving surface that extends in the x direction and the y direction and in which a plurality of light receiving elements are arranged. Then, the light receiving unit 5 receives the light emitted from the light emitting unit 4 and reflected by the target object existing in the irradiation regions, by each light receiving element.

The light receiving surface is divided into a plurality of light receiving sections corresponding to the plurality of light sources of the light emitting unit 4. In a case where the light emitting unit 4 has two light sources A1 and A2 as shown in FIG. 2, the light receiving surface is divided into two light receiving sections in the y direction. Each light receiving section has a plurality of light receiving elements that are regularly arranged. Each light receiving element receives the light emitted from the light emitting unit 4 and reflected by the target object existing in the irradiation regions, and outputs an electrical signal in response to the received light. Examples of the light receiving element include a photodiode or a phototransistor.

Each light receiving section is independently driven by the light reception drive unit 7 (see FIG. 1) to perform a light receiving operation. The drive of the light receiving section refers to changing the light receiving element included in the light receiving section from a state in which it cannot receive light to a state in which it can receive light and output an electrical signal. In addition, the phrase “independently driven” refers to driving each light receiving section into a state in which it can receive light and output an electrical signal. The light reception drive unit 7 drives each light receiving section in response to a control signal from the control unit 8 (see FIG. 1).

In addition, in a case where the light receiving element included in each light receiving section receives light, the light receiving element outputs an electrical signal corresponding to the received light to the control unit 8.

### Control Unit 8

Returning to FIG. 1, the control unit 8 is configured of a central processing unit (CPU) 81, a read only memory (ROM) 82, and a random access memory (RAM) 83.

The CPU 81 is an example of a processor, and implements each function, which will be described below, by loading various programs stored in the ROM 82 or the like into the RAM 83 and executing the programs. The RAM 83 is a memory used as a work memory or the like of the CPU 81. The ROM 82 is a memory that stores various programs and the like executed by the CPU 81.

Here, the program executed by the CPU 81 may be provided in a state of being stored in a computer-readable recording medium such as a magnetic recording medium (a magnetic tape, a magnetic disk, or the like), an optical recording medium (an optical disk or the like), a magneto-optical recording medium, or a semiconductor memory. In addition, the program executed by the CPU 81 may be provided by using a communication section such as the Internet.

In the embodiments above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device).

In the embodiments above, the term “processor” is broad enough to encompass one processor or plural processors in collaboration which are located physically apart from each other but may work cooperatively. The order of operations of the processor is not limited to one described in the embodiments above, and may be changed.

The control unit 8 controls the operation of the light emitting unit 4 through the light emission drive unit 6 and controls the operation of the light receiving unit 5 through the light reception drive unit 7.

The control unit 8 acquires the electrical signal output from the light receiving element of the light receiving unit 5. Then, the control unit 8 creates a distance image representing a distance between the distance measurement apparatus 1 and the target object based on the electrical signal acquired from the light receiving element by using the above-described ToF method. It should be noted that the control unit 8 calculates the distance between the distance measurement apparatus 1 and the target object and creates the distance image by performing predetermined arithmetic processing on the electrical signal acquired from the light receiving element of the light receiving unit 5.

### Operation Control of Light Emitting Unit 4

A control example of the operation of the light emitting unit 4 by the control unit 8 will be described with reference to the example shown in FIG. 2.

As shown in FIG. 2, irradiation regions that are irradiated with the light beams from the light sources A1 and A2 have an overlapping region where the irradiation regions overlap each other depending on the distance from the light sources. For example, the overlapping region D1 is formed on the irradiation surface 210, and the overlapping region D1 is a region in which the intensity of light to be emitted increases. In a case where the target object exists in the overlapping region D1, the intensity of light emitted to the target object is excessive, which may cause a problem.

For example, signal saturation may occur in the light receiving element that receives light reflected by the target object existing in the overlapping region D1, which may interfere with the measurement. In addition, a problem may occur due to the concentration of the intensity of light.

In a case where the target object exists in the overlapping region in which such a problem may occur, the control unit 8 turns off a part of the plurality of light sources of the light emitting unit 4 to eliminate an overlap of the overlapping region. In the example shown in FIG. 2, the control unit 8 eliminates the overlap of the overlapping region, for example, by turning off the light source A1.

In addition, the control unit 8 may be configured not to execute the control of turning off a part of the light sources in a case where the problem does not occur even in a case where the target object exists in the overlapping region. A case where no problem occurs is, for example, a case where a distance between the overlapping region into which the target object has entered and the light source is far, and the intensity of light emitted to the target object is not excessive.

In a case where an entry of the target object into the overlapping region is detected, the control unit 8 decides whether or not the overlapping region satisfies a predetermined requirement. The predetermined requirement is a criterion for whether or not a problem occurs in a case where the target object enters the overlapping region. In a case where the overlapping region satisfies a predetermined requirement, the control unit 8 turns off a part of the plurality of light sources of the light emitting unit 4 to eliminate the overlap of the overlapping region.

Here, the phrase “detecting the entry” includes “detecting that the target object has entered” and “detecting that the target object is about to enter”.

The control unit 8 detects the entry of the target object into the overlapping region based on a result of the light reception by the light receiving unit 5, and decides whether or not the overlapping region into which the target object has entered satisfies a predetermined requirement.

The predetermined requirement is determined, for example, with respect to the intensity of received light in the light receiving unit 5 or the distance between the target object that has entered the overlapping region and the light emitting unit 4. In a case of deciding whether or not a predetermined requirement is satisfied based on the intensity of received light in the light receiving unit 5, it is decided whether or not the intensity of received light exceeds a threshold value at which the signal saturation occurs in the light receiving unit 5. In a case where the intensity of received light exceeds the threshold value, the control unit 8 turns off a part of the plurality of light sources. The threshold value is a predetermined value that can be freely set, and is not limited to a case where the signal saturation occurs, and a threshold value at which a problem may occur can be set.

In a case of deciding whether or not a predetermined requirement is satisfied based on the distance between the target object that has entered the overlapping region and the light emitting unit 4, the control unit 8 measures the distance to the target object based on the result of the light reception by the light receiving unit 5, and decides whether or not the distance is shorter than a predetermined distance. In a case where the distance between the target object and the light emitting unit 4 is shorter than a predetermined distance, the control unit 8 turns off a part of the plurality of light sources.

For example, in FIG. 2, it is assumed that the overlapping region D1 of the irradiation surfaces 210 is a region that satisfies a predetermined requirement, and the overlapping region D2 of the irradiation surfaces 220 is a region that does not satisfy a predetermined requirement. In this case, in a case where the target object enters the overlapping region D1, the control unit 8 turns off any of the light sources A1 and A2 to eliminate the overlap of the overlapping region. On the other hand, even in a case where the target object enters the overlapping region D2, the control unit 8 does not execute the turning-off control.

In a case where the turning-off control is executed after detecting that the target object has entered the overlapping region in which a problem may occur, light irradiation in which a problem may occur is temporarily performed on the target object. In a case where an entry direction of the target object is constant, for example, in a case where the target object is transported by a belt conveyor, the entry can be detected before the target object enters the overlapping region by disposing the light emitting unit 4 such that the overlapping region extends in a direction intersecting the entry direction of the target object.

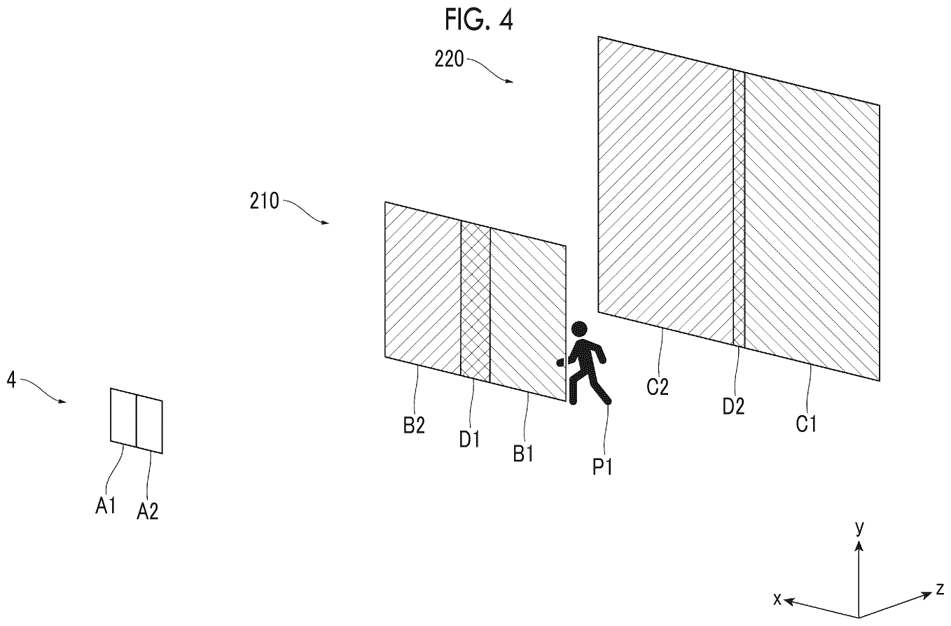

FIG. 4 is a diagram describing a relationship between the light emitting unit 4 in a case where the plurality of light sources are disposed such that the overlapping region extends in the direction intersecting the entry direction of the target object, and the irradiation surfaces 210 and 220 that are irradiated with light beams emitted from the light emitting unit 4.

In FIG. 4, similarly to FIG. 2, a left direction with respect to a direction in which the light emitting unit 4 emits the light beams is defined as an x direction, an upper direction of a paper plane is defined as a y direction, and the direction in which the light emitting unit 4 emits the light beams is defined as a z direction.

The light emitting unit 4 in FIG. 4 is disposed such that the light sources A1 and A2 shown in FIG. 2 are rotated counterclockwise by 90 degrees in the +z direction. The irradiation surfaces 210 and 220 and the overlapping regions D1 and D2 are also disposed to be rotated counterclockwise by 90 degrees in the +z direction. That is, in FIG. 4, the light sources A1 and A2 are located in the −x direction in this order, and the irradiation surfaces B1 and B2 and C1 and C2 are located in the +x direction in this order. The irradiation surfaces B1 and B2 overlap each other in the x direction to form the overlapping region D1, and the irradiation surfaces C1 and C2 overlap each other in the x direction to form the overlapping region D2.

In a case where a target object P1 advances in the +x direction and enters the irradiation surface 210, the target object P1 enters the irradiation surface B1 before entering the overlapping region D1. The light receiving unit 5 receives the light emitted from the light emitting unit 4 and reflected by the target object P1 that has entered the irradiation surface B1 and outputs the electrical signal, whereby the control unit 8 detects the entry of the target object P1 into the irradiation surface B1. Then, the control unit 8 detects that the target object P1 is about to enter the overlapping region D1, and turns off a part of the plurality of light sources to eliminate the overlap of the overlapping region.

Here, the control unit 8 determines a part of the plurality of light sources to be turned off according to the entry direction of the target object P1. In FIG. 4, the target object P1 advances in the +x direction and enters the overlapping region D1 from the irradiation surface B1 side. In this case, the control unit 8 first turns off the light source A2 to eliminate the overlap of the overlapping region D1. In this case, the irradiation surface 210 is in a state in which only the irradiation surface B1 that is irradiated with light from the light source A1 is irradiated with light from the light emitting unit 4.

Then, in a case where the target object P1 further advances in the +x direction and exits from the irradiation surface B1, the control unit 8 turns on the light source A2 and turns off the light source A1. In this case, the irradiation surface 210 is in a state in which only the irradiation surface B2 that is irradiated with light from the light source A2 is irradiated with light from the light emitting unit 4, and the overlap of the overlapping region D1 is eliminated.

In this way, the control unit 8 determines a part of the plurality of light sources to be turned off according to the entry direction of the target object, thereby preventing the target object from entering the overlapping region while maintaining the irradiation state of the target object.

In the example shown in FIG. 4, the overlapping region D1 extends in the direction orthogonal to the entry direction of the target object P1, but the present disclosure is not limited to this. As long as a position relationship is such that the target object P1 enters the irradiation surface B1 before the target object P1 enters the overlapping region D1, an angle at which the light sources A1 and A2 are disposed can be changed.

In addition, the control unit 8 may have a configuration in which the plurality of light sources A1 and A2 that irradiate the overlapping region D1 with light beams are sequentially turned on while the overlap of the overlapping region D1 is eliminated. With this configuration, the entire irradiation region may be irradiated with light without any defect while eliminating the overlap of the overlapping region D1 by turning off any one of the light sources A1 and A2.

Further, the control unit 8 may have a configuration in which, after the plurality of light sources A1 and A2 that irradiate, with light beams, the overlapping region D1 are sequentially turned on, the distance to the target object P1 is measured based on the result of the light reception by the light receiving unit 5 during a period in which the light sources A1 and A2 are sequentially turned on. With this configuration, the distance to the target object existing in the entire irradiation region may be measured without any defect while eliminating the overlap of the overlapping region D1.

In addition, in FIG. 4, a case where the light emitting unit 4 includes two light sources A1 and A2 has been described, but the light emitting unit 4 may include three or more light sources.

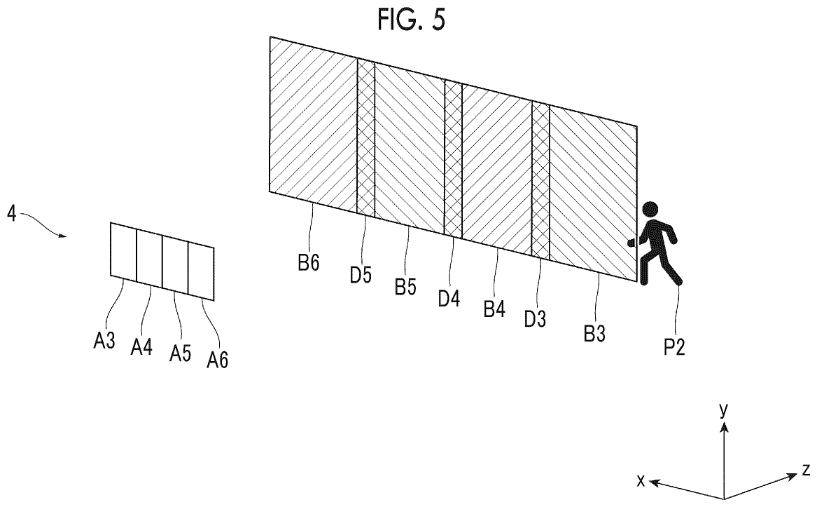

FIG. 5 is a diagram describing a relationship between the light emitting unit in a case where three or more light sources are disposed such that an overlapping region extends in the direction intersecting the entry direction of the target object, and irradiation surfaces that are irradiated with light beams emitted from the light emitting unit.

In FIG. 5, similarly to FIG. 4, a left direction with respect to a direction in which the light emitting unit 4 emits the light beams is defined as an x direction, an upper direction of a paper plane is defined as a y direction, and the direction in which the light emitting unit 4 emits the light beams is defined as a z direction.

In FIG. 5, the light emitting unit 4 includes four light sources A3, A4, A5, and A6 that are disposed along the x direction. Irradiation surfaces B3, B4, B5, and B6 are irradiated with the light beams from the light sources A3, A4, A5, and A6 shown in FIG. 5, respectively, and overlapping regions D3, D4, and D5 of the irradiation surfaces overlap each other are formed. The light sources A3, A4, A5, and A6 are located in the −x direction in this order, and the irradiation surfaces B3, B4, B5, and B6 are located in the +x direction in this order.

In a case where the target object P2 advances in the +x direction, the target object P2 first enters the irradiation surface B3. The control unit 8 detects the entry of the target object P2 into the irradiation surface B3, and further detects that the target object P2 is about to enter the overlapping region D3. Then, the control unit 8 first turns off the light source A4 to eliminate the overlap of the overlapping region D3. In a case where the target object P2 advances in the +x direction and exits from the irradiation surface B3, the control unit 8 turns on the light source A4 and turns off the light source A3.

Next, the control unit 8 detects that the target object P2 is about to enter the overlapping region D4. Then, the control unit 8 turns off the light source A5 to eliminate the overlap of the overlapping region D4. In a case where the target object P2 further advances in the +x direction and exits from the irradiation surface B4, the control unit 8 turns on the light source A5 and turns off the light source A4.

In this way, even in a case where the number of the light sources is increased, in a case where the light sources are disposed such that the overlapping region extends in the direction intersecting the entry direction of the target object, as in the case shown in FIG. 4, the control unit 8 can “detect that the target object is about to enter the overlapping region” before the target object enters the overlapping region, and the entry of the target object into the overlapping region can be prevented.

### Second Exemplary Embodiment

### Distance Measurement Apparatus 2

A distance measurement apparatus 2 to which a second exemplary embodiment is applied includes the optical device 3 and the control unit 8, as with the distance measurement apparatus 1 to which the first exemplary embodiment is applied, but a configuration of the light emitting unit is different from the configuration of the distance measurement apparatus 1. The same configurations as the configurations of the first exemplary embodiment will be described with the same reference numerals.

The distance measurement apparatus 2 includes the light receiving unit 5, the light emission drive unit 6, the light reception drive unit 7, and the control unit 8, as with the distance measurement apparatus 1, and further includes a light emitting unit 9 having a configuration different from the configuration of the light emitting unit of the distance measurement apparatus 1.

### Light Emitting Unit 9

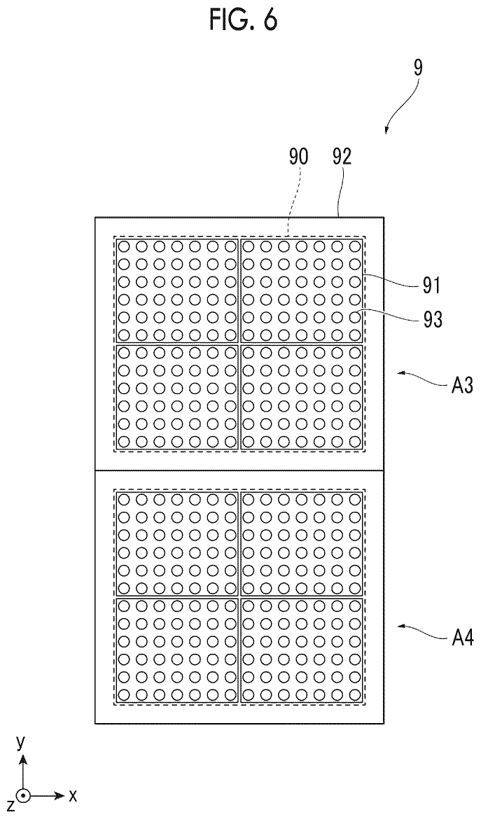

FIG. 6 is a diagram showing a configuration example of the light emitting unit 9 provided in the distance measurement apparatus 2 to which the second exemplary embodiment is applied. FIG. 6 shows a state of the light emitting unit 9 as viewed from a light emission side. Accordingly, in FIG. 6, a right direction of the paper plane is the x direction, an upper direction of the paper plane is the y direction, and a front side direction of the paper plane is the z direction.

The light emitting unit 9 includes a plurality of light sources having a light emitting surface 90 on which a plurality of VCSELs 93 are arranged. In the example shown in FIG. 6, the light emitting unit 9 includes two light sources A3 and A4. The light emitting unit 9 emits light by the light emission of the VCSELs 93.

The light emitting surface 90 is divided into a plurality of light emitting sections 91 including at least one VCSEL 93. In FIG. 6, as an example, the light emitting surface 90 is divided into a total of four light emitting sections 91 arranged in two rows in the x direction and two rows in the y direction.

Each of the light emitting sections 91 is independently driven by the light emission drive unit 6 to emit light. The light emission drive unit 6 drives each light emitting section 91 in response to a control signal from the control unit 8. Therefore, all the light emitting sections 91 do not necessarily emit light simultaneously, and only a part of the light emitting sections 91 may be turned off. The control unit 8 determines a portion of the plurality of light emitting sections 91 to be turned off. In a case where all the light emitting sections 91 are turned on or off simultaneously, the distance measurement apparatus 2 exhibits the same behavior as the distance measurement apparatus 1 to which the first exemplary embodiment is applied.

As shown in FIG. 6, in the light emitting unit 9, two light sources A3 and A4 are arranged in the y direction, and each light source has a substrate 92 and the light emitting surface 90 on which the plurality of VCSELs 93 are disposed. More specifically, the substrate 92 and the light emitting surface 90 are provided to overlap each other in a direction (the +z direction or the front side direction of the paper plane) in which light is emitted.

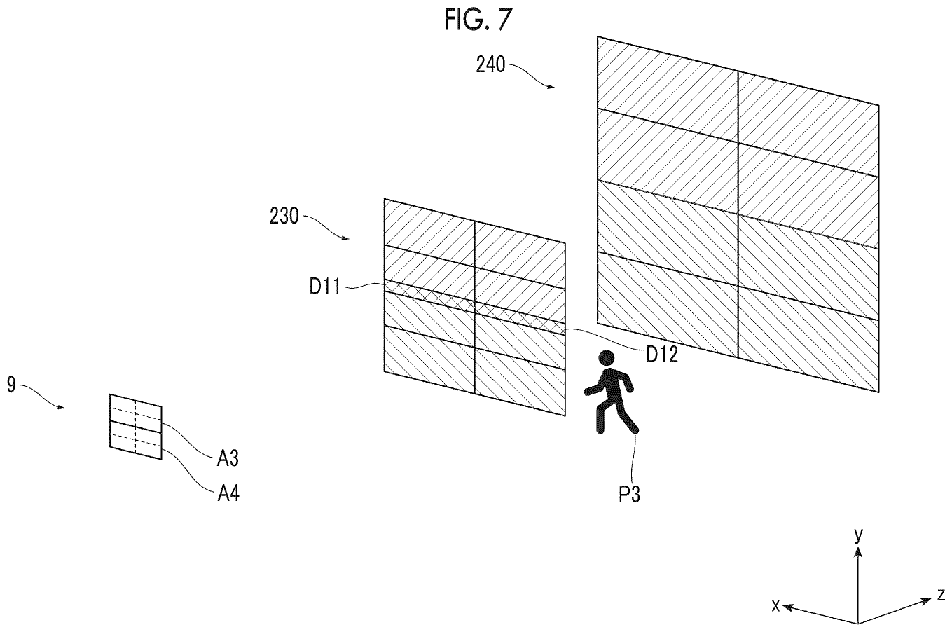

FIG. 7 is a diagram describing a relationship between the light emitting unit 9 according to the second exemplary embodiment and an irradiation region that is irradiated with light from the light emitting unit 9. In FIG. 7, similarly to FIG. 2, a left direction with respect to a direction in which the light emitting unit 9 emits the light beams is defined as an x direction, an upper direction of a paper plane is defined as a y direction, and the direction in which the light emitting unit 9 emits the light beams is defined as a z direction.

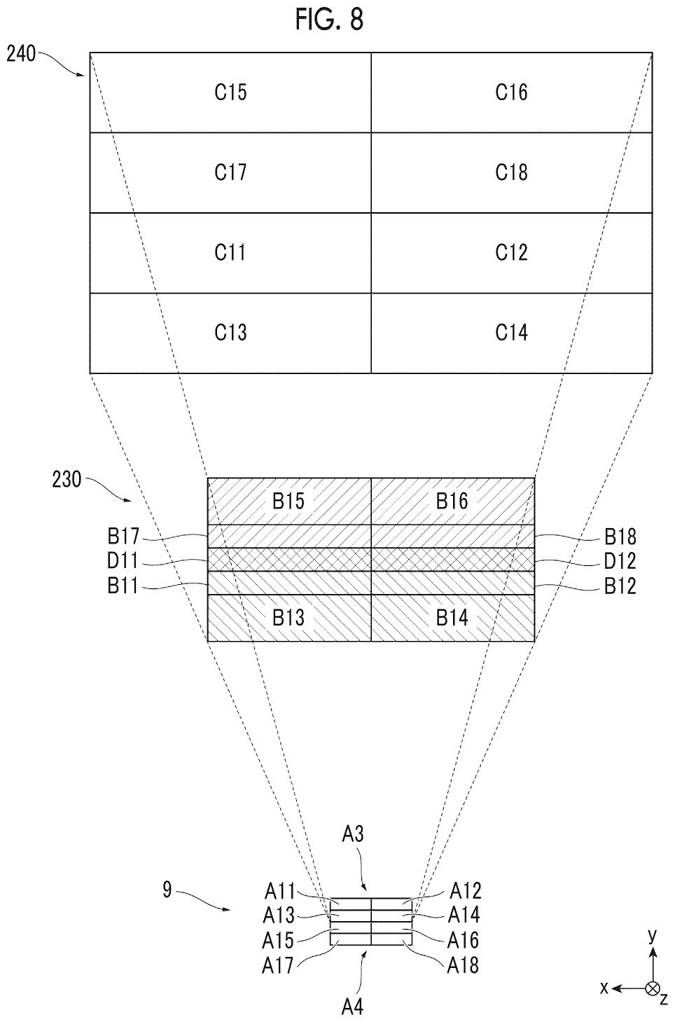

In FIG. 7, the light emitting unit 9 includes two light sources A3 and A4 that are located in the −y direction in this order, and each light source is divided into a total of four light emitting sections 91 as shown in FIG. 6. As shown in FIG. 8 to be described below, the respective light emitting sections 91 are distinguished as light emitting sections A11 to A18 in order from the upper left side (the end in the +x direction and the +y direction) facing the light irradiation direction (the +z direction). The light source A3 is divided into the light emitting sections A11 and A14, and the light source A4 is divided into the light emitting sections A15 and A18. FIG. 7 shows an example of a case where the light beams from the light sources A3 and A4 are emitted to intersect each other.

Irradiation regions that are irradiated with the light beams from the light sources A3 and A4 may have an overlapping region where the irradiation regions overlap each other depending on the distance from the light sources.

Irradiation surfaces 230 and 240 are surfaces that are irradiated with light beams from the light emitting unit 9, the surfaces being orthogonal to a direction in which light is emitted at a certain distance in a direction in which the light emitting unit 9 emits light, in the irradiation regions. In FIG. 7, the irradiation surface 240 is located at a distance at which uniform irradiation is applied to the irradiation surface without an overlap between the irradiation regions, and the irradiation surface 230 is located in a direction (the −z direction) close to the light emitting unit 9 with respect to the irradiation surface 240.

As shown in FIG. 8 to be described below, the irradiation surface 230 is formed of irradiation surfaces B11 to B14 that are irradiated with light beams from the light emitting sections A11 to A14 of the light source A3 and irradiation surfaces B15 to B18 that are irradiated with light beams from the light emitting sections A15 to A18 of the light source A4. In a case where the light beams from the light sources A3 and A4 are emitted to intersect each other, the irradiation surfaces B15 to B18 and B11 to B14 are located on the irradiation surface 230 in order from the upper left side (the end in the +x direction and the +y direction) facing the light irradiation direction (the +z direction). Partial regions of the irradiation surfaces B11 and B17 overlap each other and partial regions of the irradiation surfaces B12 and B18 overlap each other in the y direction, and an overlapping region D11 and an overlapping region D12 are formed.

The irradiation surface 240 is formed of irradiation surfaces C11 to C14 that are irradiated with the light beams from the light emitting sections A11 to A14 of the light source A3 and irradiation surfaces C15 to C18 that are irradiated with the light beams from the light emitting sections A15 to A18 of the light source A4. The irradiation surfaces C15 to C18 and C11 to C14 are located in order from the left upper side (the end in the +x direction and the +y direction) facing the light irradiation direction (the +z direction).

FIG. 8 is a diagram describing a relationship between the light emitting unit 9 according to the second exemplary embodiment and the irradiation surfaces 230 and 240 that are irradiated with light beams emitted from the light emitting unit 9. In FIG. 8, a left direction of the paper plane is defined as an x direction, an upper direction of the paper plane is defined as a y direction, and a back side direction of the paper plane is defined as a z direction. In FIG. 8, the light emitting unit 9 and the irradiation surfaces 230 and 240 are shown to be shifted in an up-down direction (+y direction) of the paper plane, but the light emitting unit 9 and the irradiation surfaces 230 and 240 are located to face each other. In FIG. 8, the light emitting unit 4 is located in the front side direction (−z direction) of the paper plane, the irradiation surface 230 is located in the back side direction (+z direction) of the paper plane, and the irradiation surface 240 is located in the back side direction (+z direction).

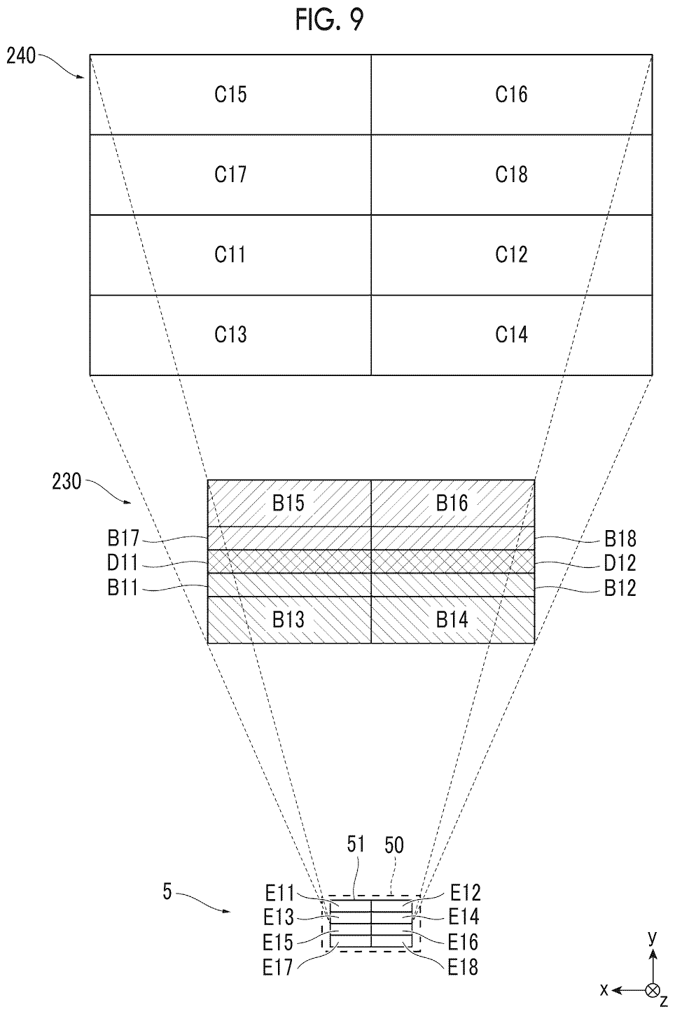

FIG. 9 is a diagram describing a relationship between a light receiving surface 50 of the light receiving unit 5 according to the second exemplary embodiment and the irradiation surfaces 230 and 240 described above. In FIG. 9, similarly to FIG. 8, a left direction of the paper plane is defined as an x direction, an upper direction of the paper plane is defined as a y direction, and a back side direction of the paper plane is defined as a z direction. In FIG. 9, the light receiving surface 50 and the irradiation surfaces 230 and 240 are shown to be shifted in the up-down direction (+y direction) of the paper plane, but the light receiving surface 50 and the irradiation surfaces 230 and 240 are disposed to face each other. In FIG. 9, the light receiving unit 5 (light receiving surface 50) is located in the front side direction (−z direction) of the paper plane, and the irradiation surfaces 230 and 240 are located in the back side direction (+z direction) of the paper plane.

The light receiving surface 50 is divided into a plurality of light receiving sections 51 corresponding to the light emitting sections 91 (see FIG. 7) of the light emitting surface 90 and the irradiation surfaces 230 and 240. In the example of FIG. 9, the light receiving surface 50 is divided into eight light receiving sections 51 arranged in two rows in the x direction and four rows in the y direction. The respective light receiving sections 51 are distinguished as light receiving sections E11 to E18 in order from the upper left side (the end in the +x direction and the +y direction) in FIG. 9.

Each light receiving section 51 receives light emitted from the light emitting unit 9 and reflected by the target object existing on the corresponding irradiation surfaces 230 and 240. Each light receiving section 51 is independently driven by the light reception drive unit 7 (see FIG. 1) to perform a light receiving operation.

### Operation Control of Light Emitting Unit 9

A control example of the operation of the light emitting unit 9 by the control unit 8 will be described with reference to the example shown in FIG. 7.

Similarly to the first exemplary embodiment, in a case where the target object exists in the overlapping region in which such a problem may occur, the control unit 8 turns off a part of the plurality of light sources of the light emitting unit 9 to eliminate an overlap of the overlapping region. The plurality of light sources A3 and A4 included in the light emitting unit 9 are each divided into the plurality of light emitting sections 91, and the control unit 8 can eliminate the overlap of the overlapping region by turning off a part of the light emitting sections 91.

For example, it is assumed that the overlapping region D12 shown in FIG. 7 is an overlapping region satisfying a predetermined requirement where a problem may occur in a case where the target object enters the overlapping region. In this case, in a case where a target object P3 enters the overlapping region D12, the control unit 8 turns off a part of the light emitting sections 91 to eliminate the overlap of the overlapping region D12. The overlapping region D12 is formed by the overlap between the irradiation surface B12 and the irradiation surface B18, and the control unit 8 eliminates the overlap of the overlapping region D12 by turning off any one of the corresponding light emitting sections A12 and A18.

In addition, the control unit 8 sequentially turns on the light emitting section A12 and the light emitting section A18 while eliminating the overlap of the overlapping region D12. As a result, the entire irradiation region may be irradiated with light without any defect while eliminating the overlap of the overlapping region D12.

### Processing Procedure by Control Unit 8

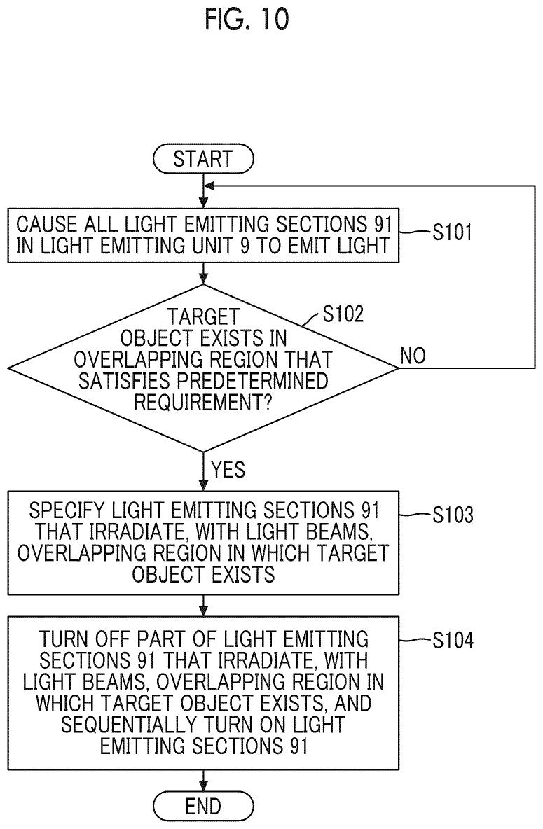

Subsequently, processing performed by the control unit 8 will be described. FIG. 10 is a flowchart showing a procedure of the processing by the control unit 8.

First, the control unit 8 causes all the light emitting sections 91 in the light emitting unit 9 to emit light (step S101).

Next, the control unit 8 decides whether or not the target object exists in the overlapping region that satisfies a predetermined requirement (step S102). The overlapping region that satisfies the predetermined requirement is an overlapping region in which a problem may occur in a case where the target object enters the overlapping region. In step S102, the control unit 8 decides whether or not the target object exists based on the result of the light reception by the light receiving unit 5.

In a case where the target object does not exist in the overlapping region that satisfies the predetermined requirement (NO in step S102), the control unit 8 returns to step S101, and continues the processing.

On the other hand, in a case where the target object exists in the overlapping region that satisfies the predetermined requirement (YES in step S102), the control unit 8 specifies the light emitting sections 91 that irradiate, with light beams, the overlapping region in which the target object exists (step S103). The control unit 8 specifies the corresponding light emitting sections 91 as the light emitting sections that irradiate the overlapping region with light beams based on the result of the light reception by each light receiving section 51.

For example, in FIG. 7, in a case where the control unit 8 detects the entry into the overlapping region D12, the control unit 8 specifies the light emitting sections A12 and A18 as the light emitting sections that irradiate, with light beams, the overlapping region in which the target object exists.

Next, the control unit 8 turns off a part of the light emitting sections 91 that irradiate, with light beams, the overlapping region in which the target object exists, and sequentially turns on the light emitting sections 91 (step S104). In FIG. 7, in a case where the control unit 8 detects the entry into the overlapping region D12 in FIG. 7, the control unit 8 turns off any one of the light emitting sections A12 and A18 to eliminate the overlap of the overlapping region D12. Then, the control unit 8 sequentially turns on the light emitting sections A12 and A18 and irradiates the entire irradiation region with light without any defect.

As described above, the series of processing related to the operation control of the light emitting unit 9 by the control unit 8 is ended.

As described above, since each light source is divided into the plurality of light emitting sections 91, in the distance measurement apparatus 2, compared to the distance measurement apparatus 1, more finer turning-off control can be performed.

For example, in the example shown in FIG. 7, in a case where a first target object exists on the irradiation surface 240 on which the uniform irradiation is performed without the overlap between the irradiation regions, and the P3 as a second target object enters the overlapping regions D11 and D12 that satisfy the predetermined requirement, the control unit 8 turns off a part of the light emitting sections 91 so as to eliminate the overlap of the overlapping region into which the second target object has entered while maintaining the irradiation of the first target object with light beams.

For example, in FIG. 7, it is assumed that the first target object exists on the irradiation surface C13. Here, in a case where the second target object enters the overlapping region D11 that satisfies the predetermined requirement, in a case where each light source is not divided into the plurality of light emitting sections 91, the control unit 8 sequentially turns off and turns on the light sources A3 and A4 in order to suppress the excessive irradiation of the second target object with light beams, and thus the irradiation of the first target object with light beams cannot be maintained. Since each light source is divided into the plurality of light emitting sections 91, the control unit 8 may eliminate the overlap of the overlapping region D11 while maintaining the irradiation of the first target object with light beams by sequentially turning off and turning on the light emitting sections A11 and A17.

### Modification Example

In FIG. 7, a case where the light emitting unit 9 has two light sources A3 and A4 has been described, but the light emitting unit 9 may have three or more light sources.

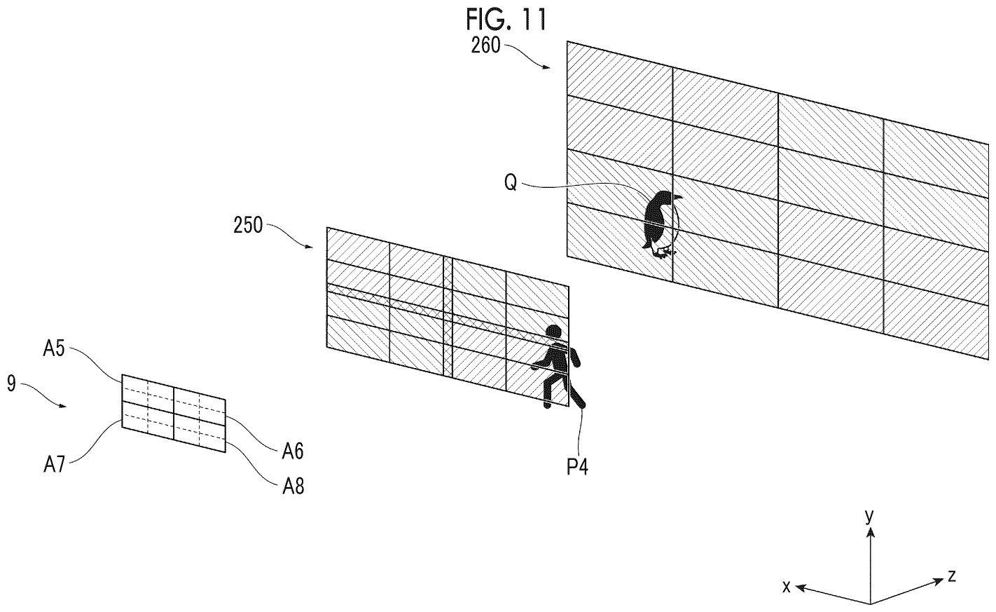

FIG. 11 is a diagram describing a relationship between the light emitting unit 9 in a case where the light emitting unit 9 according to the second exemplary embodiment has four light sources A5, A6, A7, and A8, and an irradiation region that is irradiated with light from the light emitting unit 9.

In FIG. 11, similarly to FIG. 7, a left direction with respect to a direction in which the light emitting unit 9 emits the light beams is defined as an x direction, an upper direction of a paper plane is defined as a y direction, and the direction in which the light emitting unit 9 emits the light beams is defined as a z direction. In FIG. 11, the light emitting unit 9 includes four light sources A5, A6, A7, and A8 that are located in order from the upper left side (the end in the +x direction and the +y direction) facing the light irradiation direction (the +z direction), and each light source is divided into a total of four light emitting sections 91 as shown in FIG. 6.

FIG. 11 shows an example of a case where the light beams from the light sources A5, A6, A7, and A8 are emitted to intersect each other. Irradiation regions that are irradiated with the light beams from the light sources A5, A6, A7, and A8 may have an overlapping region where the irradiation regions overlap each other depending on the distance from the light sources.

Irradiation surfaces 250 and 260 are surfaces that are irradiated with light beams from the light emitting unit 9, the surfaces being orthogonal to a direction in which light is emitted at a certain distance in a direction in which the light emitting unit 9 emits light, in the irradiation regions. In FIG. 11, the irradiation surface 260 is located at a distance at which uniform irradiation is applied to the irradiation surface without an overlap between the irradiation regions, and the irradiation surface 250 is located in a direction (the −z direction) close to the light emitting unit 9 with respect to the irradiation surface 260.

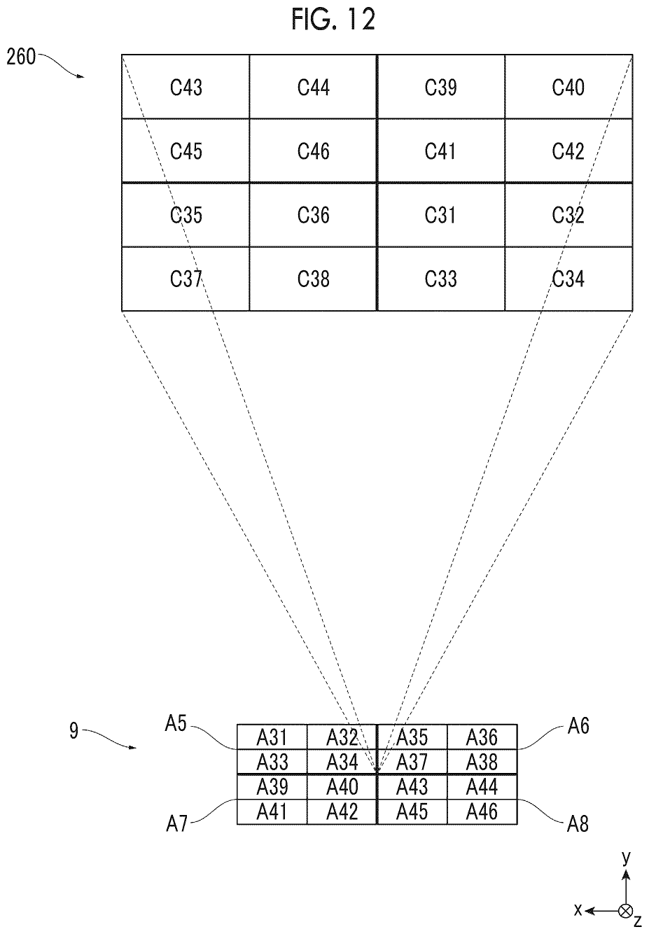

The relationship between the light emitting unit 9 and the irradiation region that is irradiated with light from the light emitting unit 9 shown in FIG. 11 will be described with reference to FIGS. 12 to 14.

FIG. 12 is a diagram describing a relationship between the light emitting unit 9 in a case where the light emitting unit 9 according to the second exemplary embodiment has four light sources A5, A6, A7, and A8, and the irradiation surface 260 that is irradiated with light from the light emitting unit 9. In FIG. 12, a left direction of the paper plane is defined as an x direction, an upper direction of the paper plane is defined as a y direction, and a back side direction of the paper plane is defined as a z direction.

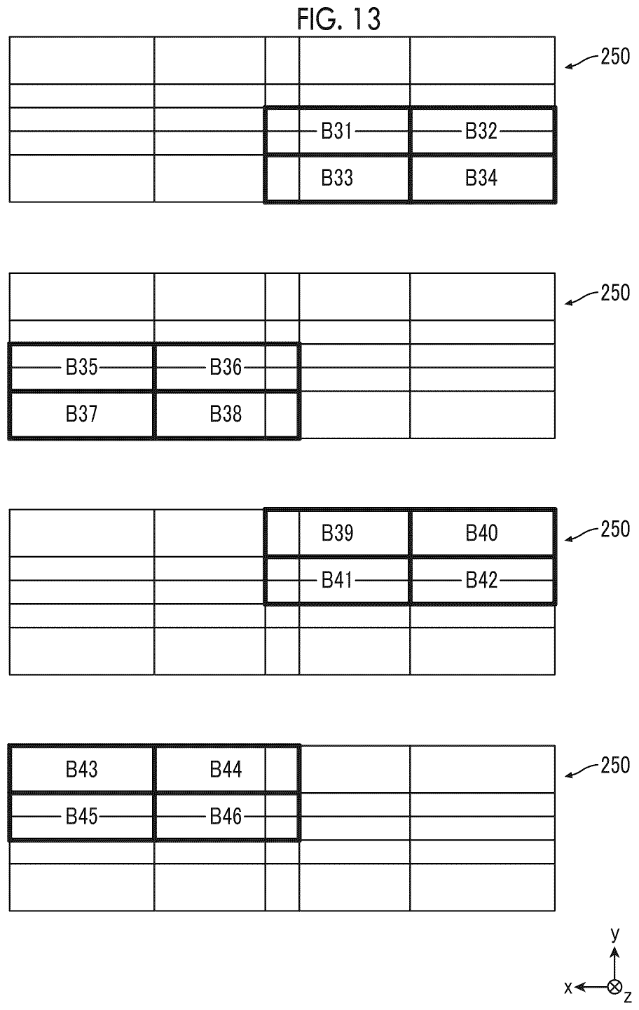

FIG. 13 is a diagram describing a relationship between the light emitting unit 9 in a case where the light emitting unit 9 according to the second exemplary embodiment has four light sources A5, A6, A7, and A8, and an irradiation surface that is irradiated with light from each of the light sources A5, A6, A7, and A8. In FIG. 13, a left direction of the paper plane is defined as an x direction, an upper direction of the paper plane is defined as a y direction, and a back side direction of the paper plane is defined as a z direction. In FIG. 13, portions of the irradiation surface 250, which are irradiated with light beams from the respective light sources, are shown as separate figures shifted in the up-down direction (+y direction) of the paper plane, but each figure represents the same irradiation surface 250.

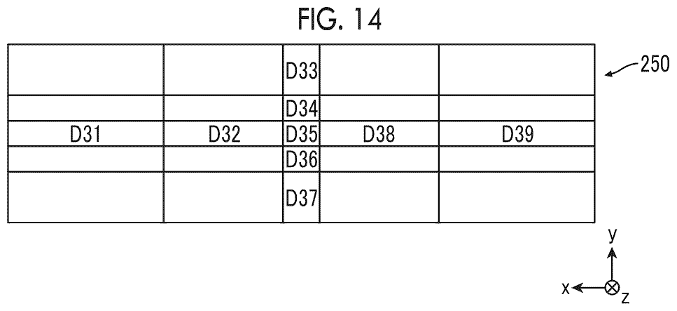

FIG. 14 is a diagram describing an overlapping region between irradiation regions in a case where the light emitting unit 9 according to the second exemplary embodiment has four light sources A5, A6, A7, and A8. FIG. 14 shows an overlapping region in a case where the respective irradiation surfaces 250 shown in FIG. 13 are overlapped. In FIG. 14, a left direction of the paper plane is defined as an x direction, an upper direction of the paper plane is defined as a y direction, and a back side direction of the paper plane is defined as a z direction.

As shown in FIG. 12, the light sources A5, A6, A7, and A8 of the light emitting unit 9 are each divided into four light emitting sections 91 (see FIG. 6), and are distinguished as light emitting sections A31 to A46 in order from the upper left side (the end in the +x direction and ty direction) facing the light irradiation direction (the +z direction). The light source A5 is divided into the light emitting sections A31 to A34, the light source A6 is divided into the light emitting sections A35 to A38, the light source A7 is divided into the light emitting sections A39 to A42, and the light source A8 is divided into the light emitting sections A43 to A46. In FIG. 12, the light emitting unit 9 and the irradiation surface 260 are shown to be shifted in an up-down direction (+y direction) of the paper plane, but the light emitting unit 9 and the irradiation surface 260 are located to face each other. In FIG. 12, the light emitting unit 9 is located in the front side direction (−z direction) of the paper plane, and the irradiation surface 260 is located in the back side direction (+z direction) of the paper plane.

The irradiation surface 260 is formed of irradiation surfaces C31 to C34 that are irradiated with light beams from the light emitting sections A31 to A34 of the light source A5, irradiation surfaces C35 to C38 that are irradiated with light beams from the light emitting sections A35 to A38 of the light source A6, irradiation surfaces C39 to C42 that are irradiated with light beams from the light emitting sections A39 to A42 of the light source A7, and irradiation surfaces C43 to C46 that are irradiated with light beams from the light emitting sections A43 to A46 of the light source A8. On the irradiation surface 260, the irradiation surfaces C43 to C46, C39 to C42, C35 to C38, and C31 to C34 are located in order from the left upper side (the end in the +x direction and the +y direction) facing the light irradiation direction (the +z direction).

As shown in FIG. 13, the irradiation surface 250 is formed of irradiation surfaces B31 to B34 that are irradiated with the light beams from the light emitting sections A31 to A34 of the light source A5, irradiation surfaces B35 to B38 that are irradiated with the light beams from the light emitting sections A35 to A38 of the light source A6, irradiation surfaces B39 to B42 that are irradiated with the light beams from the light emitting sections A39 to A42 of the light source A7, and irradiation surfaces B43 to B46 that are irradiated with the light beams from the light emitting sections A43 to A46 of the light source A8.

In a case where the light beams from the respective light sources are emitted to intersect each other, the irradiation surfaces B43 to B46, B39 to B42, B35 to B38, and B31 to B34 are located on the irradiation surface 250 in order from the upper left side (the end in the +x direction and the ty direction) facing the light irradiation direction (the +z direction).

As shown in FIG. 14, partial regions of the irradiation surfaces shown in FIG. 13 overlap each other, and overlapping regions D31 to D39 are formed. More specifically, partial regions of the irradiation surface B35 and the irradiation surface B45 overlap each other, partial regions of the irradiation surface B36 and the irradiation surface B46 overlap each other, partial regions of the irradiation surface B31 and the irradiation surface B41 overlap each other, and partial regions of the irradiation surface B32 and the irradiation surface B42 overlap each other in the y direction, and the overlapping regions D31, D32, D38, and D39 are formed. In addition, partial regions of the irradiation surface B39 and the irradiation surface B44 overlap each other, partial regions of the irradiation surface B46 and the irradiation surface B41 overlap each other, partial regions of the irradiation surface B36 and the irradiation surface B31 overlap each other, and partial regions of the irradiation surface B38 and the irradiation surface B33 overlap each other in the x direction, and the overlapping regions D33, D34, D36, and D37 are formed. Further, partial regions of the irradiation surfaces B31, B36, B41, and B46 overlap each other in the x direction and the y direction, and the overlapping region D35 is formed.

The light receiving surface 50 of the light receiving unit 5 is divided into a plurality of light receiving sections 51 corresponding to the light emitting sections 91 (see FIG. 12) of the light emitting surface 90 and the irradiation surfaces 250 and 260. Each light receiving section 51 receives light emitted from the light emitting unit 9 and reflected by the target object existing on the corresponding irradiation surfaces 250 and 260. Each light receiving section 51 is independently driven by the light reception drive unit 7 (see FIG. 1) to perform a light receiving operation.

### Operation Control of Light Emitting Unit 9

Here, returning to FIG. 11, the operation control of the light emitting unit 9 in a case where a target object Q exists on the irradiation surface 260 and a target object P4 enters the overlapping region of the irradiation surfaces 250 will be described. The target object Q is an example of a first target object, and the target object P4 is an example of a second target object.

In a case where the control unit 8 detects the entry of the target object P4 into the overlapping region of the irradiation surface 250 based on the result of the light reception by the light receiving unit 5, the control unit 8 decides whether or not the overlapping region into which the target object P4 has entered satisfies a predetermined requirement. In a case where the overlapping region into which the target object P4 has entered satisfies the predetermined requirement, the control unit 8 eliminates the overlap of the overlapping region by turning off a part of the light emitting sections 91 that irradiate the overlapping region with light beams.

In a case where the target object P4 enters any of the overlapping regions D31, D32, D33, D34, D36, D37, D38, and D39, the control unit 8 eliminates the overlap of the overlapping region by turning off a part of the light emitting sections 91 that irradiate the respective overlapping regions with light beams. In this case, in a case where the target object Q exists on the irradiation surface 260, the overlap of the overlapping region is eliminated while maintaining the irradiation of the target object Q with light beams. For example, in a case where the target object Q exists on the irradiation surface C32 and the target object P4 enters the overlapping region D39, the control unit 8 turns off the light emitting section A42 among the light emitting sections 91 that irradiate the overlapping region D39 with light beams, and maintains the light emitting section A32 in a turned-on state to eliminate the overlap of the overlapping region D39.

A configuration may be adopted in which the plurality of light emitting sections 91 that irradiate, with light beams, the overlapping region into which the target object P4 has entered are sequentially turned on to irradiate the irradiation regions with light beams without any defect.

In a case where the target object P4 enters the overlapping region D35, the control unit 8 turns off three of the light emitting sections A31, A36, A41, and A46 that irradiate the overlapping region D35 with light beams to eliminate the overlap of the overlapping region D35. In a case where the target object Q exists on any of the irradiation surfaces C31, C36, C41, and C46, the control unit 8 turns off the light emitting section 91 corresponding to the irradiation surface on which the target object Q does not exist, and maintains the light emitting section 91 corresponding to the irradiation surface on which the target object Q exists in a turned-on state to eliminate the overlap of the overlapping region D39.

The control unit 8 may be configured to sequentially turn on the light emitting sections A31, A36, A41, and A46 and irradiate the irradiation regions with light beams without any defect.

In addition, for example, in a case where the target object P4 is long in the y direction and the target object P4 also exists on the irradiation surfaces B33 and B38, a configuration may be adopted in which all the light emitting sections A31, A36, A41, and A46 are turned off and the irradiation state of the target object P4 is maintained by the irradiation from the light emitting section A33 or the light emitting section A38.

In addition, as shown in FIG. 4, even in a case where the light emitting unit 4 is disposed such that the overlapping region extends in the direction intersecting the entry direction of the target object, a configuration may be adopted in which the light emitting surface 90 is divided into the plurality of light emitting sections 91. With this configuration, more finer turning-off control can be performed as compared with a case where the distance measurement apparatus 1 is used, and a period in which the target object cannot be detected can be made shorter.

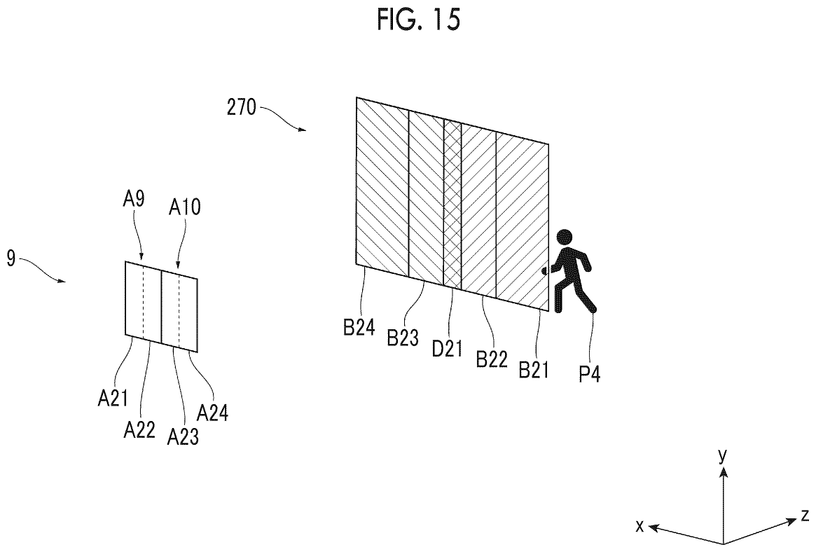

FIG. 15 is a diagram describing a relationship between the light emitting unit 9 in a case where a plurality of light sources of the light emitting unit 9 in which the light emitting surface 90 is divided into the plurality of light emitting sections 91 are disposed such that an overlapping region extends in the direction intersecting the entry direction of the target object, and an irradiation surface 270 that is irradiated with light emitted from the light emitting unit 9. In FIG. 15, similarly to FIG. 11, a left direction with respect to a direction in which the light emitting unit 9 emits the light beams is defined as an x direction, an upper direction of a paper plane is defined as a y direction, and the direction in which the light emitting unit 9 emits the light beams is defined as a z direction.

The light emitting unit 9 shown in FIG. 15 has two light sources A9 and A10, and the light sources A9 and A10 are located in this order in the −x direction. The light sources A9 and A10 are each divided into two light emitting sections 91 in the x direction, and the light source A9 has light emitting sections A21 and A22, and the light source A10 has light emitting sections A23 and A24. The light emitting sections A21, A22, A23, and A24 are located in this order in the −x direction. In addition, FIG. 15 shows an example of a case where light beams from the light sources A9 and A10 are emitted to intersect each other.

The irradiation surface 270 is a surface that is irradiated with light from the light emitting unit 9, the surface being orthogonal to a direction in which light is emitted at a certain distance in a direction in which the light emitting unit 9 emits light, in the irradiation regions. The irradiation surface 270 is formed of an irradiation surface B21 that is irradiated with light beams from the light emitting section A21, an irradiation surface B22 that is irradiated with light beams from the light emitting section A22, an irradiation surface B23 that is irradiated with light beams from the light emitting section A23, and an irradiation surface B24 that is irradiated with light beams from the light emitting section A24.

In a case where the light beams from the light sources A9 and A10 are emitted to intersect each other, the light emitting sections A21, A22, A23, and A24 are located in the −x direction in this order, whereas the irradiation surfaces B21, B22, B23, and B24 are located in the +x direction in this order. Partial regions of the irradiation surface B22 and the irradiation surface B23 in the x direction overlap each other, and an overlapping region D21 is formed.

In a case where the target object P4 advances in the +x direction and enters the irradiation surface 270, the target object P4 enters the irradiation surfaces B21 and B22 before entering the overlapping region D21. In a case where the target object P4 enters the irradiation surfaces B21 and B22, the light receiving unit 5 receives the light emitted from the light emitting unit 9 and reflected by the target object P4 and outputs the electrical signal, whereby the control unit 8 detects the entry of the target object P4 into the irradiation surfaces B21 and B22. Then, the control unit 8 detects that the target object P4 is about to enter the overlapping region D21, and turns off a part of the plurality of light emitting sections 91 to eliminate the overlap of the overlapping region.

Here, the control unit 8 determines a part of the plurality of light emitting sections 91 to be turned off according to the entry direction of the target object P4. In FIG. 15, the target object P4 advances in the +x direction and enters the overlapping region D21 from the irradiation surface B22 side. In this case, the control unit 8 first turns off the light emitting section A23 to eliminate the overlap of the overlapping region D21. In this case, the irradiation surface 270 is in a state in which the irradiation surfaces B21, B22, and B24 are irradiated with light from the light emitting unit 9.

Then, in a case where the target object P4 further advances in the +x direction and exits from the irradiation surface B22, the control unit 8 turns on the light emitting section A23 and turns off the light emitting section A22. In this case, the irradiation surface 270 is in a state in which the irradiation surfaces B21, B23, and B24 are irradiated with light from the light emitting unit 9, and the overlap of the overlapping region D21 is eliminated.

In this way, the control unit 8 determines a part of the plurality of light emitting sections 91 to be turned off according to the entry direction of the target object, thereby preventing the target object from entering the overlapping region while maintaining the irradiation state of the target object.

An example in which each light receiving section is independently driven to perform the light receiving operation has been shown, the present disclosure is not limited to this. The light reception may be performed in all the light receiving sections. In a case where a light emission timing of each light emitting section is made different and the light receiving operation of only the light receiving section corresponding to the light emitting section is not adopted, the light receiving operation may be affected by an influence of multipath noise or the like. Even in such a case, by making the light emission timing of each light emitting section different from each other, power used at once in a case of irradiating a wide area with light can be reduced as compared to a case where the timing is not made different.

### Supplementary Note

(((1)))

A light emitting device comprising:

a light emitting unit that irradiates different irradiation regions with light beams from a plurality of light sources in parallel; and

a control unit that turns off a part of the plurality of light sources that irradiate, with light beams, an overlapping region where the irradiation regions by the respective light sources overlap each other in a case where an entry of a target object into the overlapping region is detected.

(((2)))

The light emitting device according to (((1))), wherein the light emitting unit is disposed such that the overlapping region extends in a direction intersecting an entry direction of the target object.

(((3)))

The light emitting device according to (((2))), wherein the control unit determines the part of the plurality of light sources to be turned off according to the entry direction of the target object.

(((4)))

The light emitting device according to (((1))), wherein the plurality of light sources each have a plurality of light emitting sections, and the control unit determines a portion of the plurality of light emitting sections to be turned off.

(((5)))

A distance measurement apparatus comprising:

the light emitting device according to (((1)));

a light receiving unit that receives light beams emitted from the light emitting unit and reflected by the target object; and

a distance measurement unit that measures a distance to the target object based on a result of the light reception by the light receiving unit.

(((6)))

The distance measurement apparatus according to (((5))), wherein the control unit turns off a part of the light sources based on the result of the light reception by the light receiving unit.

(((7)))

The distance measurement apparatus according to (((6))), wherein the control unit detects the entry of the target object into the overlapping region based on the result of the light reception by the light receiving unit, and turns off a part of the light sources in a case where an intensity of light received by the light receiving unit exceeds a predetermined value.

(((8)))

The distance measurement apparatus according to (((6))), wherein the control unit turns off a part of the light sources in a case where the distance to the target object is shorter than a predetermined distance.

(((9)))

The light emitting device according to (((1))), wherein the plurality of light sources each have a plurality of light emitting sections, and in a case where a first target object exists in the irradiation regions and an entry of a second target object into the overlapping region satisfying a predetermined requirement is detected, the control unit turns off a part of the plurality of light emitting sections so as to eliminate an overlap of the overlapping region into which the second target object has entered while maintaining irradiation of the first target object with light beams.

(((10)))

The light emitting device according to (((1))), wherein, in a case where the entry of the target object into the overlapping region is detected, the control unit sequentially turns on the plurality of light sources that irradiate, with light beams, the overlapping region while eliminating an overlap of the overlapping region.

(((11)))

The distance measurement apparatus according to (((5))),

wherein the distance measurement unit measures, after the plurality of light sources that irradiate, with light beams, the overlapping region are sequentially turned on, the distance to the target object based on the result of the light reception by the light receiving unit during a period in which the light sources are sequentially turned on.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a light emitting unit that irradiates different irradiation regions with light beams from a plurality of light sources in parallel; and
a control unit that turns off a part of the plurality of light sources that irradiate, with light beams, an overlapping region where the irradiation regions by the respective light sources overlap each other in a case where an entry of a target object into the overlapping region is detected.

2. The light emitting device according to claim 1,
wherein the light emitting unit is disposed such that the overlapping region extends in a direction intersecting an entry direction of the target object.

3. The light emitting device according to claim 2,
wherein the control unit determines the part of the plurality of light sources to be turned off according to the entry direction of the target object.

4. The light emitting device according to claim 1,
wherein the plurality of light sources each have a plurality of light emitting sections, and
the control unit determines a portion of the plurality of light emitting sections to be turned off.

5. A distance measurement apparatus comprising:
the light emitting device according to claim 1;
a light receiving unit that receives light beams emitted from the light emitting unit and reflected by the target object; and
a distance measurement unit that measures a distance to the target object based on a result of the light reception by the light receiving unit.

6. The distance measurement apparatus according to claim 5,
wherein the control unit turns off a part of the light sources based on the result of the light reception by the light receiving unit.

7. The distance measurement apparatus according to claim 6,
wherein the control unit detects the entry of the target object into the overlapping region based on the result of the light reception by the light receiving unit, and turns off a part of the light sources in a case where an intensity of light received by the light receiving unit exceeds a predetermined value.

8. The distance measurement apparatus according to claim 6,
wherein the control unit turns off a part of the light sources in a case where the distance to the target object is shorter than a predetermined distance.

9. The light emitting device according to claim 1,
wherein the plurality of light sources each have a plurality of light emitting sections, and
in a case where a first target object exists in the irradiation regions and an entry of a second target object into the overlapping region satisfying a predetermined requirement is detected, the control unit turns off a part of the plurality of light emitting sections so as to eliminate an overlap of the overlapping region into which the second target object has entered while maintaining irradiation of the first target object with light beams.

10. The light emitting device according to claim 1,
wherein, in a case where the entry of the target object into the overlapping region is detected, the control unit sequentially turns on the plurality of light sources that irradiate, with light beams, the overlapping region while eliminating an overlap of the overlapping region.

11. The distance measurement apparatus according to claim 5,
wherein the distance measurement unit measures, after the plurality of light sources that irradiate, with light beams, the overlapping region are sequentially turned on, the distance to the target object based on the result of the light reception by the light receiving unit during a period in which the light sources are sequentially turned on.
